(19) United States
(12) Patent Application Publication
(10) Pub. No.: US 2011/0114368 A1
(43) Pub. Date: May 19, 2011

(54) ELECTRONIC CIRCUIT COMPONENT AND METHOD FOR MANUFACTURING SAME

(76) Inventors: Hiroshi Nakano, Tokai (JP); Hitoshi Suzuki, Hitachi (JP); Toshio Haba, Tokai (JP); Haruo Akahoshi, Hitachi (JP)

(21) Appl. No.: 13/001,848

(22) PCT Filed: Jun. 25, 2009
(86) PCT No.: PCT/JP2009/002908

§ 371 Date: Dec. 29, 2010

(30) Foreign Application Priority Data
Jun. 30, 2008 (JP) 2008-169763

(51) Int. Cl. H05K 1/02; H05K 3/10

(52) U.S. Cl. 174/251; 29/846

(57) ABSTRACT

A small-sized electronic circuit component comprising micro-wiring and a method for manufacturing the same are provided. The electronic circuit component is manufactured by a manufacturing method comprising the steps of forming a recessed portion which is to be a three-dimensional wiring in the surface of an insulating base material of the electronic circuit component comprising the wiring, forming a first metal layer which is to be an electroplated conductive layer on the surface of the insulating base material including the recessed portion, selectively forming a second metal layer which is to be the wiring only in the recessed portion which is to be the wiring, and removing the first metal layer formed on the surface other than in the recessed portion which is to be the wiring.

### TECHNICAL FIELD

The present invention relates to an electronic circuit component and a method for manufacturing the same.

### BACKGROUND ART

Recently, electronic devices, typically including cellular phones, are increasingly reduced in size and increased in performance, and electronic components mounted thereon themselves have been reduced in size. Correspondingly, improvement of the wiring densities of circuit boards is attempted. Therefore, multilayering and micro-wiring of circuit boards are carried out, and circuit boards are increasingly formed into shapes which allow denser mounting. In addition, diverse characteristics are also required for circuit boards as the diversity of electronic component increases, and in particular, cubic circuits having three-dimensional wiring patterns have been actively suggested.

A known method for forming such cubic circuits includes an MID substrate (Molded Interconnect Device), which is a cubic circuit substrate having an uneven configuration and a three-dimensional surface on which circuits are formed.

Such substrates of cubic circuits are applied to electronic/optical devices for which size and weight reduction is required. A known method for forming a circuit on a surface of a substrate having a cubic shape comprises steps of forming a plating underlayer on an insulative surface of the substrate, removing the boundary between a circuit portion in the plating underlayer and a non-circuit portion by laser light irradiation, forming plating for forming circuits on the circuit portion, and then performing light etching for removing the plating underlayer of the non-circuit portion (for example, refer to Patent Literature 1).

It is also possible to employ a method which comprises steps of forming a plating layer consisting of a metallic material (conductive material) on a substrate, applying a photosensitive etching resist on a surface of the plating layer, performing exposure by irradiating a plurality of planes which are not on the same plane as the substrate with the etching resist applied thereon via mask films with laser beam, reproducing the resist pattern by development, leaving the plating layer in the portions on which the etching resist is applied and chemically etching the rest of the plating layer portions, forming a three-dimensional wiring pattern on a plurality of planes on the substrate, and then mounting optional electronic components in predetermined positions of the wiring pattern.

A suggested method for manufacturing a three-dimensional circuit component by using injection-molded component is, for example, so-called two-color molding, in which a resin containing a plating catalyst is molded, and then an insulating resin is molded in portions other than those which are to be a circuit, so that the circuit is finally formed by nonelectrolytic plating using the exposed plating catalyst.

Patent Literature 1 discloses a method for manufacturing a circuit board characterized by forming a plating underlayer of a catalyst for metal plating, a plating catalyst compound, a metal film or others on a surface of an insulative base material, and irradiating at least the boundary region between circuit portions of an insulative base material and non-circuit portions with an electromagnetic wave such as laser correspondingly to the pattern of the non-circuit portions so that the plating underlayer in these portions irradiated with an electromagnetic wave such as laser are removed while leaving the unirradiated portions, and then forming plating on the plating underlayer.

Patent Literature 2 discloses a method for manufacturing of a cubic circuit substrate forming a circuit on a surface of a molded product characterized by comprising the steps of forming a resist layer on the surface of the molded product having a cubic shape, removing the resist layer in the portions which are to be a circuit from the resist layer by using laser light and forming a titanium film on the surface of the molded product including the resist layer, and removing the titanium film formed on the surface of the resist layer by removing the resist layer and then plating the surface of the titanium film remaining on the surface of the molded product to form the circuit.

Patent Literature 3 discloses a method for manufacturing a three-dimensional injection molded circuit component characterized by comprising the steps of forming a resin layer comprising a resin which is soluble in a low-boiling point solvent on a surface of a primary molded product constituting a substrate of a circuit component other than in portions in which a circuit is to be formed to obtain a secondary molded product, applying a catalyst to portions in which a circuit is to be formed on a surface of the secondary molded product, bringing the secondary molded product into contact with vapor of the low-boiling point solvent and/or droplets of the low-boiling point solvent after the application of the catalyst to dissolve and remove the resin layer, and forming a conductor circuit layer in the portions with the catalyst applied by nonelectrolytic plating after the dissolution and removal of the resin layer.

Patent Literature 4 discloses a method for manufacturing a cubic circuit component by forming a metal layer on a plastic molded product, and forming a circuit pattern by photoetching, the method characterized by forming the metal layer on the entire surface of the molded product by nonelectrolytic plating, and then applying, exposing and developing both a negative electrodeposition resist and a positive electrodeposition resist to form the circuit pattern.

Patent Literature 5 discloses a method for manufacturing a cubic circuit substrate in which a conductor layer having a predetermined pattern comprising a conductive material is formed on a surface of a dielectric substrate having a predetermined shape comprising a synthetic resin material, the method characterized by comprising the steps of forming the dielectric substrate having the predetermined shape by using a catalyst-containing synthetic resin material which contains a catalyst for nonelectrolytic plating, forming a hydrolyzable high-molecular material resin mask on this dielectric substrate in a manner of covering surface portions other than these by exposing surface portions where the conductor layer is to be formed having the predetermined pattern in the surface of this dielectric substrate, subjecting this resin mask and the entire surface of the above dielectric substrate exposed out of this resin mask to a surface roughening process, removing the above resin mask from the above dielectric substrate, and forming the conductive layer having a predetermined pattern on the surface of the above dielectric substrate by the nonelectrolytic plating.

### PRIOR ART DOCUMENTS

### Patent Documents

Patent Literature 1: Japanese Patent Application Laid-Open No. H07-66533
Patent Literature 2: Japanese Patent Application Laid-Open No. 2007-173546
Patent Literature 3: Japanese Patent Application Laid-Open No. 2005-217156
Patent Literature 4: Japanese Patent Application Laid-Open No. H11-220244
Patent Literature 5: Japanese Patent No. 3715866

### SUMMARY OF THE INVENTION

### Object to be Achieved by the Invention

As disclosed in Patent Literature 1, a possible method for forming the three-dimensional circuit component is direct writing onto the resist by the laser, but this method is problematic in that it requires the complicated steps of precisely applying a resist onto a foundation having a complicated shape and aligning the wirings with high accuracy in order to form fine wiring and that achievement of micro-wiring and thus the size reduction of the component are difficult. In addition, as described in Patent Literature 3, when a photoresist is used, the alignment of an upper surface and lower surface of the component is necessary and positional shift of side surfaces is likely to occur, making achievement of micro-wiring difficult. Furthermore, these methods are also problematic in that when the intervals between wirings is narrow, migration is generated on the side surfaces of the wirings by the influence of electric fields, which prevents achieving high-density wiring. Furthermore, these methods are problematic in that it is difficult to process the side surfaces with high precision by laser irradiation and exposure and render the side surfaces vertical. In addition, there has been the problems that since the wiring is projecting from the substrate, the wiring portion may peel off during handling of the foundation if its adhesion of is insufficient and that the wiring may be damaged due to contact with other components.

Patent Literatures 2 and 4 suggest such methods that expose the catalyst for nonelectrolytic plating only in the wiring portions by employing the so-called two-color molding as a molding method. However, this method requires a resin containing palladium that is a large amount of an expensive metal in its molding process, and it is also difficult to form an insulating resin which is molded later highly precisely, preventing achieving fine wiring.

In addition, although wiring can be formed on the outer surface of the structural body by the methods as mentioned above, it is difficult to form wiring on the inner surfaces of structural bodies such as cylinders and pipes by such methods, pausing a problem in size reduction of circuit components.

It is an object of the present invention to provide an electronic circuit component on which a three-dimensional wiring pattern which can cope with a density growth and miniaturization of wiring is formed with precision and at low costs, and a method for manufacturing the same.

### Means for Achieving the Object

An electronic circuit component of the present invention having a pattern of three-dimensional wiring on an insulating base material which serves as a foundation for an electronic circuit is characterized in that the wiring is embedded in the insulating base material. In addition, the electronic circuit component is also characterized in that the insulating base material has a recessed portion which is to be a wiring on the surface thereof in the form of a three-dimensional pattern, and the recessed portion has a first metal layer and a second metal layer which are to be the wirings therein.

An electronic circuit component of the present invention is manufactured by a method for forming wiring comprising the steps of forming the recessed portion which is to be a wiring on the surface of the insulating base material of the electronic circuit component having three-dimensional wiring, forming the first metal layer which is to be an electric conductive layer for electrolysis plating on the surface of the base material including the recessed portion, forming the second metal wiring layer which is to be the wiring only within the recessed portion which is to be the wiring selectively, and removing the first metal layer formed on the surface other than in the recessed portion which are to be the wiring.

In addition, it is preferable that the second metal layer is copper; a plating solution used in the step of forming the second metal layer is a plating solution comprising a substance which increases a deposition overvoltage for a metal which is to be wirings on the surface of the first metal layer, an acidic copper sulfate electroplating solution having a property of having a potential region in which the current value when the electrode rotates at 1000 rpm is 1/100 or less compared to a current value when the electrode is stationary in a polarization curve obtained by measurement with a rotating disk electrode, or an acidic copper sulfate electroplating solution having a property that a current value when the electrode rotates at 1000 rpm is 1/100 or less compared to a current value when the electrode is stationary in the range of 100 to 200 mV with respect to standard hydrogen electrode potential and the current value when the electrode rotates is larger than the current value when the electrode is stationary in the range of −100 mV or less in the polarization curve obtained by measurement with the rotating disk electrode.

### Effect of the Invention

According to the present invention, it is possible to provide an electronic circuit component having a three-dimensional wiring structure with accurate fine wiring. It is also possible to provide a highly reliable and small-sized electronic circuit component by providing the wiring structure having the above barrier film.

### BRIEF DESCRIPTION OF THE DRAWINGS

FIG. 1 is a perspective view illustrating an electronic circuit component of an embodiment according to the present invention.

FIG. 2 is a flowchart showing a manufacture process of an electronic circuit component which is the embodiment according to the present invention.

FIG. 3 is a partial cross-sectional view illustrating the manufacture process of an electronic circuit component which is an example according to the present invention.

FIG. 4 is a perspective view illustrating an electronic circuit component of another example according to the present invention.

FIG. 5 is a partial cross-sectional view illustrating the manufacture process of an electronic circuit component which is another example according to the present invention.

FIG. 6 is a partial cross-sectional view illustrating the state of wiring of an electronic circuit component of an example according to the present invention after plating.

FIG. 7 is a graph showing the polarization characteristics of an electroplating solution of an example according to the present invention.

FIG. 8 is a perspective view and a partial cross-sectional view illustrating an electronic circuit component of another example according to the present invention.

FIG. 9 is a perspective view and a partial cross-sectional view illustrating an electronic circuit component of another example according to the present invention.

### MODE FOR CARRYING OUT THE INVENTION

The present invention relates to a fine wiring, a structural body and an electronic component using the same which can be suitably used for an electronic component (electronic circuit component) having a three-dimensional wiring.

The electronic circuit component of the present invention (copper circuit component) is a copper circuit component (electronic circuit component) comprising at least an insulating base material and a pattern of recessed portions which are to be a three-dimensional wiring on the surface thereof, a first metal layer (also referred to as a first metal member.) in the recessed portions and a second metal layer (also referred to as a second metal member.) which is to be a wiring.

The formation of the wiring in the recessed portions in such a manner allows separation of the wirings with good insulation.

Therefore, the copper circuit (also referred to as an electronic circuit.) having high-density wiring can be formed without compromising the reliability between wirings, and a small-sized copper circuit component can be provided. A further characteristic of the wiring board in the present invention is good adhesion between the wirings and the insulating base material since it has wirings within the recessed portions.

The electronic circuit component of the present invention is an electronic circuit component having a pattern of a three-dimensional wiring on an insulating base material which serves as a foundation of an electronic circuit, characterized in that the wiring is embedded within the insulating base material.

The electronic circuit component of the present invention is characterized in that the insulating base material has a recessed portion which is to be a wiring on the surface thereof in the form of a three-dimensional pattern, and the recessed portion has a first metal layer and a second metal layer which are to be the wirings therein.

The electronic circuit component of the present invention is characterized in that a minimum width of the wiring is 20 μm or less.

The electronic circuit component of the present invention is characterized in that the height-to-width ratio of the wiring is 1.5 or higher at the maximum.

The electronic circuit component of the present invention is characterized in that a barrier film is formed on the bottom surface and side surface of the wiring.

The electronic circuit component of the present invention is characterized in that the barrier film comprises nickel or cobalt as a main component.

The electronic circuit component of the present invention is characterized in that the wiring is provided on at least one of the outer and inner surfaces of the insulating base material.

The electronic circuit component of the present invention is characterized in that the electronic circuit component comprises a multilayered circuit portion in which a plurality of layers of circuit patterns are laminated by interposing an insulating layer on at least one surface of the insulating base material.

The electronic circuit component of the present invention is characterized in that at least one portion of the shape of the insulating base material is a curved surface.

The electronic circuit component of the present invention is characterized in that the shape of the insulating base material is spherical.

A method for manufacturing an electronic circuit component of the present invention is characterized by the steps of forming a recessed portion which is to be a wiring on the surface of an insulating base material of an electronic circuit component having three-dimensional wiring, forming a first metal layer which is to be an electric conductive layer for electrolysis plating on the surface of the insulating base material including the recessed portion, forming a second metal wiring layer which is to be the wiring only within the recessed portion which is to be the wiring selectively, and removing the first metal layer formed on the surface other than in the recessed portion which are to be the wiring.

The method for manufacturing the electronic circuit component of the present invention is characterized in that the second metal layer is copper.

The method for manufacturing the electronic circuit component of the present invention is characterized in that the step of forming the second metal layer is conducted by electroplating using a plating solution containing a substance which increases deposition overvoltage for a metal which is to be the wiring on the surface of the first metal layer.

The method for manufacturing the electronic circuit component of the present invention is characterized in that the plating solution used in the formation of the second metal layer is a copper sulfate electroplating solution, and has a property of having a potential region in which a current value when a rotating disk electrode rotates at 1000 rpm is 1/100 or less of that when the electrode is stationary in a polarization curve obtained by measurement with the electrode.

The method for manufacturing the electronic circuit component of the present invention is characterized in that the plating solution used in the formation of the second metal layer is a copper sulfate electroplating solution, and is such that the current value when the rotating disk electrode rotates at 1000 rpm to the current value when the electrode is stationary is 1/100 or less in the range of 100 to 200 mV, and the current value when the electrode rotates is larger than the current value when the electrode is stationary in the range of −100 my or less with respect to standard hydrogen electrode potential in the polarization curve obtained by measurement with the electrode.

The method for manufacturing the electronic circuit component of the present invention is characterized in that the copper plating solution comprises at least one of cyanine dye and derivatives thereof.

The method for manufacturing the electronic circuit component of the present invention is characterized in that the cyanine dye is represented by the following Chemical Formula (1) (n is any one of 0, 1, 2 and 3).

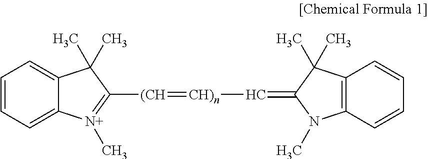

The method for manufacturing the electronic circuit component of the present invention is characterized in that the first metal layer and the second metal layer are both copper.

The method for manufacturing the electronic circuit component of the present invention is characterized in that the first metal layer is nickel, cobalt, chromium, tungsten, palladium or titanium, or an alloy comprising at least any one of nickel, cobalt, chromium, tungsten, palladium and titanium, and the second metal layer is copper.

The electronic circuit component of the present invention is characterized by including an insulating base material having a recessed portion, and a wiring embedded within the recessed portion, wherein the wiring comprises a first metal member closely fitted onto the internal surface of the recessed portion, and a second metal member closely fitted onto the first metal member.

The electronic circuit component of the present invention is characterized in that the second metal member fills the recessed portion.

The electronic circuit component of the present invention is characterized by having a three-dimensional circuit pattern.

The electronic circuit component of the present invention is characterized in that the first metal member is a barrier film for suppressing the diffusion of elements constituting the second metal member into the insulating base material.

The electronic circuit component of the present invention is characterized in that the barrier film comprises nickel or cobalt as a main component.

The electronic circuit component of the present invention is characterized in that the barrier film comprises nickel-boron.

The electronic circuit component of the present invention is characterized in that the barrier film comprises tungsten or molybdenum.

The electronic circuit component of the present invention is characterized in that the first metal member is an alloy comprising at least one element selected from the group consisting of nickel, cobalt, chromium, tungsten, palladium and titanium, and the second metal member comprises copper.

The electronic circuit component of the present invention is characterized in that both of the first metal member and the second metal member are copper or copper alloy.

The electronic circuit component of the present invention is characterized in that the insulating base material has a hollow cubic shape, and the wiring is provided on the outer and/or inner surfaces of the insulating base material.

The electronic circuit component of the present invention is characterized in that a multilayered circuit is constituted by stacking a plurality of electronic circuit components.

The electronic circuit component of the present invention is characterized in that the insulating base material has a curved surface.

The electronic circuit component of the present invention is characterized in that the insulating base material is spherical.

The electronic circuit component of the present invention is characterized in that the minimum width of the wiring is 20 μm or less.

The electronic circuit component of the present invention is characterized in that the height-to-width ratio of the wiring is 1.5 or higher at the maximum.

A method for manufacturing an electronic circuit component of the present invention comprising an insulating base material having a recessed portion, and a wiring embedded within the recessed portion, in which the wiring comprises a first metal member closely fitted onto the internal surface of the recessed portion, and a second metal member closely fitted onto the first metal member is characterized by comprising an insulating base material formation step in which the insulating base material having a desired shape is formed, a base film formation step in which the first metal member is formed, a wiring formation step in which the second metal member is selectively formed inside the recessed portion, and an unnecessary metal portion removal step in which unnecessary portions of the first metal member and/or the second metal member are removed.

The method for manufacturing the electronic circuit component of the present invention is characterized in that a plating solution used in the wiring formation step comprises a substance which increases deposition overvoltage.

The method for manufacturing the electronic circuit component of the present invention is characterized in that the plating solution comprises copper sulfate, and has a property of having a potential region in which the current density when the electrode rotates at 1000 rpm is 1/100 or less of that when the electrode is stationary in a polarization curve obtained by measurement with a rotating disk electrode.

The method for manufacturing the electronic circuit component of the present invention is characterized in that a current density when the electrode rotates at 1000 rpm to the current density when the electrode is stationary is 1/100 or less in the range of 100 to 200 mV, and the current density when the electrode rotates at 1000 rpm is larger than the current density when the electrode is stationary in the range of −100 mV or less with respect to standard hydrogen electrode potential in a polarization curve obtained by measurement with a rotating disk electrode.

The method for manufacturing the electronic circuit component of the present invention is characterized in that the plating solution comprises at least one of cyanine dye and derivatives thereof.

Embodiments of the present invention will be described below in detail with reference to drawings.

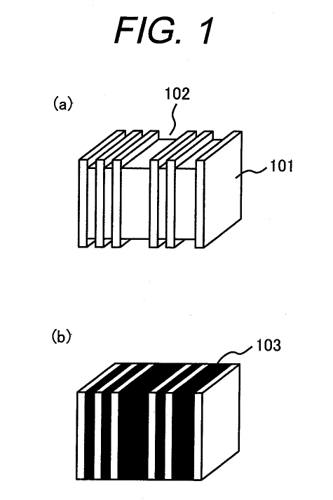

FIG. 1 is a schematic diagram showing an electronic circuit component (including copper circuit component. Hereinafter, also referred to simply as a component.) of an embodiment according to the present invention. In FIG. 1, a cuboid-shaped insulating material having trenches (recessed portions) provided thereon is used as a base material.

In FIG. 1(a), an insulating base material 101 is formed of an insulating material, and has recessed portions 102 which are to be a wiring pattern. FIG. 1(b) shows the state that wirings 103 are embedded in the recessed portions 102 in FIG. 1(a). Herein, the wirings 103 are composed of an electric conductor (conductor), which is typically copper or a copper alloy in many cases.

The recessed portions 102 can be formed into optional shapes such as trenches, holes, etc., so that they fit the shape of the wirings 103. The width of the recessed portions 102 is not particularly limited, but can be, for example, 0.1 μm to 1 mm. In particular, it is preferably in the range from 1 to 100 μm since it allows easy processing. In addition, various widths and shapes may be combined. The intervals between the recessed portions 102 are not particularly limited, but can be 0.1 μm to 1 mm. In particular, they are preferably in the range from 1 to 100 μm since it allows easy processing.

The insulating base material 101 forms the structure of the circuit component, and is molded into a predetermined cubic shape depending on the purpose, place (place to be mounted) and method of use of the circuit component and other conditions.

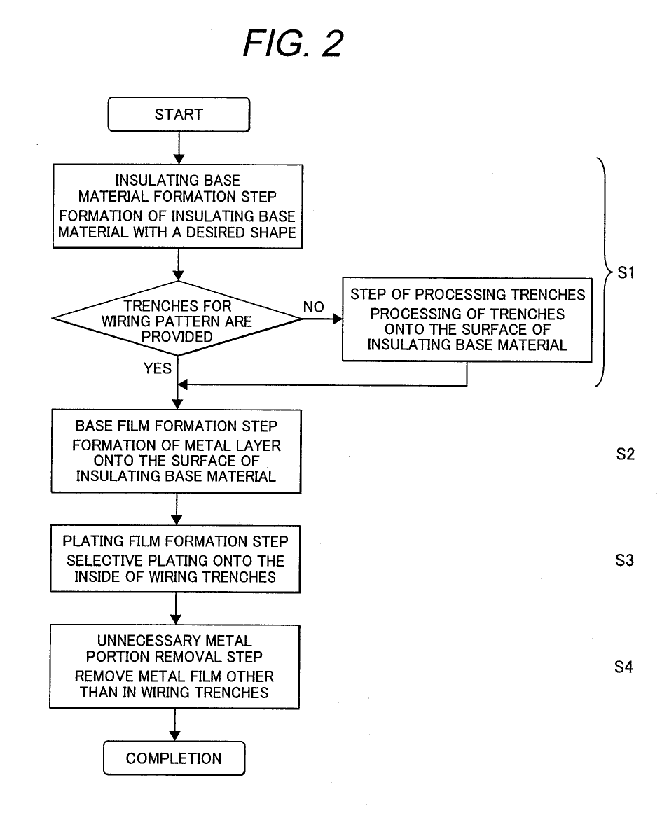

FIG. 2 is a flowchart showing the manufacture process of a copper circuit component which is an embodiment according to the present invention.

The method for manufacturing of the present invention is a method for manufacturing a cubic circuit substrate forming a circuit on the surface of a molded product. As shown in this flowchart, an insulating base material formation step (S1) in which a molded product having a desired cubic shape and trenches for wiring pattern are formed, a base film formation step (S2) in which a nickel phosphorus film which is to be a first metal film is formed, a plating film formation step (S3) in which the insides of the trenches (recessed portions) are selectively plated by subjecting the surface of the above-mentioned first metal film to electroplating to form a circuit (wiring), and a step (S4) in which unnecessary portions of the first metal film are removed are performed in the order stated.

The insulating base material formed in S1 mentioned above has recessed portions (trenches for wiring pattern) and projecting portions. The first metal film (base film) formed in S2 mentioned above is formed on the surface of these recessed portions and projecting portions in an approximately uniform thickness.

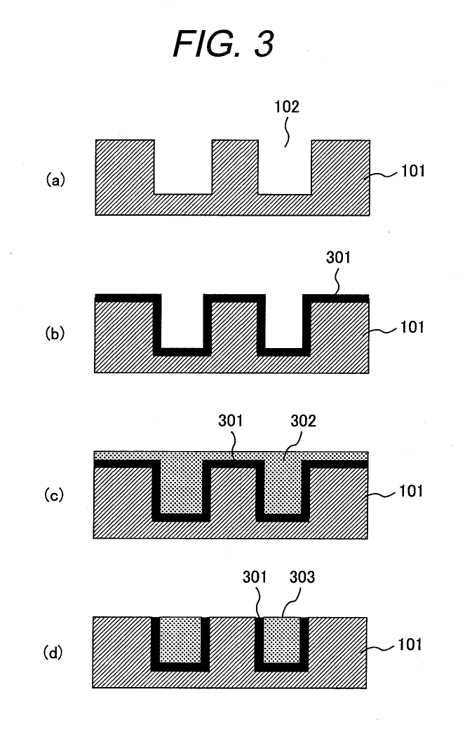

FIG. 3 is a partial cross-sectional view showing the manufacture process of a copper circuit component which is an embodiment according to the present invention. FIGS. 3(a) to (d) show the states of the component after steps S1 to S4 in FIG. 2 have been performed, respectively.

FIG. 3(a) shows a partial cross section of the molded product, which is in the state that the recessed portions 102 (wiring trenches) are formed on the insulating base material 101 which has been integrally molded. FIG. 3(b) shows the state that the first metal film 301 is formed on the surface of the insulating base material 101. FIG. 3(c) shows the state that the second metal film 302 is formed on the surface of the first metal film 301. FIG. 3(d) is the state that the metal film in the portions other than in the recessed portions 102 (wiring trenches) have been removed and wiring 303 are provided in the recessed portions 102.

Molding of the molded product is carried out, for example, by means of injection molding, press molding and other methods. When the entire molded product is formed of an insulating material, examples of usable insulating materials include ceramic materials such as glass, alumina, aluminum nitride and silicon carbide; and resin materials such as PPS (polyphenylene sulfide), PEEK (polyether ether ketone), polyphthalamide, PTFE (polyethylene terephthalate), acrylic resins, polycarbonate, polystyrene, polypropylene, poly cyclic oxides, epoxy resins, polyimide, LCP (liquid crystal polyester resin) and PEI (polyetherimide).

The molded product formed in this step may be such that at least its surface forming the circuit is formed of an insulating material, and molded products such as metal core substrates which are manufactured by covering the surface of copper, aluminum and the like with an insulating material may be also used. In addition, the base material can be also formed by rapid prototyping method in which conventionally known light hardening resins, such as epoxy resins and acrylic resins are irradiated with a laser beam.

The shape of the insulating base material 101 may be not only combinations of planes, but also those having curved surfaces and combinations of spheres, cylinders, cones and planes, among others. Furthermore, the insulating base material may be in a spherical shape, or can be formed into any shape depending on the required functions.

The recessed portions 102 which are to be a wiring pattern are formed on the three-dimensional surface of the insulating base material 101, constituting a three-dimensional copper circuit component. The recessed portions 102 may be formed in advance by molding during injection molding, or may be formed separately by imprinting on the surface of the molded article.

The first metal film 301 (also referred to as first metal layer or first metal member) formed on the recessed portions 102 can be formed by a dry method such as a sputtering process, a wet method such as nonelectrolytic plating, or a coating method such as the sol gel process. The low-cost wet method is preferable, and nonelectrolytic plating is more preferable. When employing nonelectrolytic plating, copper, and nickel alloys such as nickel-phosphorus, nickel-phosphorus-boron, nickel-boron, nickel-tin-phosphorus, nickel-iron-phosphorus, nickel-zinc-phosphorus, nickel-tungsten-phosphorus and nickel-molybdenum-phosphorus; cobalt alloys such as cobalt-phosphorus and cobalt-boron; copper alloys such as copper-tin and copper-zinc; silver alloys such as silver and tin-silver; and mixtures thereof can be used for plating.

When elements such as tungsten and molybdenum are added to an electroless plating solution containing nickel-phosphorus, nickel-boron, cobalt-phosphorus, cobalt-boron and others, an electroless plating film (first metal film 301) formed by plating becomes an alloy containing elements such as tungsten and molybdenum which are refractory metals, and functions as a barrier film which suppresses diffusion of copper, i.e., a constituent element of the main wiring material (also referred to as second metal member or second metal layer.). Accordingly, the reliability of the wiring 303 is advantageously improved. In addition, nickel-boron is more preferable since it is excellent in adhesion between the insulating base material 101 and the second metal film 302 (wiring material).

The thickness of the first metal layer 103 is not particularly limited, but it is preferably 0.01 μm to 5 μm, and more preferably 0.05 μm to 2 μm. When this thickness is less than 0.01 μm, it is difficult to suppress the diffusion of copper. When the layer is caused to deposit thickly, the deposition time becomes too long and the manufacture cost is increased. Therefore, the thickness is desirably 5 μm or less.

A characteristic of the method for copper plating on the insulating base material having recessed portions on its surface in the present invention is forming electrolytic copper plating preferentially within the recessed port ions by using an additive which suppresses the plating reaction. This method allows deposition of almost selective plating substantially only within the recessed portions. That is, the plating within the recessed portions can be made sufficiently thicker than that of the substrate surface portions other than in the recessed portions, and therefore the copper plating film on the surface of the substrate other than in the recessed portions can be easily removed.

As the additive to be used for copper plating, a substance which suppresses the plating reaction and loses a plating reaction suppressing effect simultaneously with the progression of the plating reaction is suitable. The effect of the additive for suppressing the plating reaction can be checked by seeing if deposition overpotential of metal becomes higher when the additive is added to the plating solution. The effect that the additive loses the plating reaction suppressing effect simultaneously with the progression of the plating reaction can be checked by the fact that the deposition overpotential of the metal to be plated becomes higher as a flow rate of the plating solution is higher. This means that the plating reaction suppressing effect becomes higher as a supply speed of the additive to a first metal layer surface is higher. When the additive loses the plating reaction suppressing effect, the additive is decomposed and is changed into another substance or is reduced so as to be changed into a substance having a different oxidation number.

The reason why plating can be deposited in the recessed portion approximately selectively by carrying out plating using the plating solution containing such an additive is described below. When plating is carried out by using such an additive, the additive loses its effect on the surface of the first metal layer simultaneously with the progression of the plating reaction. As a result, an effective additive concentration relating to the plating reaction is reduced on the surface of the first metal layer. When the concentration of the additive is reduced, the additive is supplied by diffusion from the solution along the concentration gradient. A distance from a bulk plating solution in the recessed portion is longer than that in the substrate surface. Therefore, the supply of the additive is slow in the recessed portion, and the increase speed of the additive concentration due to diffusion is low. For this reason, a state that its additive concentration is lower than that in the substrate surface is maintained in the recessed portion. Since this additive has the plating reaction suppressing effect, the plating reaction in the recessed portion where the additive concentration is low is not suppressed, and a plating film can be grown selectively in the recessed portion.

In the plating solution having such a characteristic, it is preferable that a rotating disk electrode has a potential area where a current value when the electrode rotates at 1000 rpm is 1/100 or less compared to a current value when the electrode is stationary in a polarization curve obtained by measurement on the rotating disk electrode.

FIG. 7 is a graph showing the polarization characteristics of an electroplating solution of an embodiment according to the present invention.

This polarization characteristic was determined by using a rotating disk with a diameter of 5 mm.

In such a plating solution, current density B at 1000 rpm is 1/100 or less than current density A when the electrode is stationary (0 rpm) at a certain electric potential E′.

Additives which can be suitably used for the plating solution include those which desirably contain at least one of cyanine dyes and its derivatives, such as 2-[(1,3-Dihydro-1,3,3-trimethyl-2H-indol-2-ylidene)-methyl]-1,3,3-trimethyl-3H-indolium perchlorate, 2-[3-(1,3-Dihydro-1,3,3-trimethyl-2H-indol-2-ylidene)-1-propenyl]-1,3,3-trimethyl-3H-indolium chloride, 2-[5-(1,3-Dihydro-1,3,3-trimethyl-2H-indol-2-ylidene)-1,3-pentadienyl]-1,3,3-trimethyl-3H-indolium iodide, 2-[7-(1,3-Dihydro-1,3,3-trimethyl-2H-indol-2-ylidene)-1,3,5-heptatrienyl]-1,3,3-trimethyl-3H-indolium iodide, 3-Ethyl-2-[5-(3-ethyl-2(3H)-benzothiazolylidene)-1,3-pentadienyl]benzothiazolium iodide and JanusGreen B.

As the plating solution of the present invention copper, a plating solution with the additive stated above added to a plating solution containing copper ions, sulfuric acid and chloride ions is used. That is, a plating solution containing copper sulfate is used.

Usable copper ions include those prepared by dissolving copper sulfate pentahydrate and copper oxide, and usable sulfuric acid and chloride ions include sodium chloride and hydrochloric acid, among others. In addition to the above-mentioned components, Bis (3-sulfopropyl)disulfide that is a conventionally known accelerator, and polyethylene glycol that is a surfactant, among others, may be contained. The concentration of copper ions is preferably 7.5 to 70 g/dm³; the concentration of sulfuric acid is preferably 50 to 250 g/dm³; and the concentration of chloride ions is preferably about 10 to 150 mg/dm³.

A plating method which can be suitably used is the suspended type electroplating method in which components are fixed to fixtures and racks, but when structural components are minute, barrel plating may be employed.

According to the present invention, it is possible to obtain a copper circuit component having a fine three-dimensional wiring formed thereon having the minimum wiring width of 20 μm or less and the height-to-width ratio of the wiring of 1.5 or higher at the maximum.

The method for manufacturing the copper circuit component of the present invention will be now described with reference to drawings. FIG. 2 is a flowchart of the manufacture of the copper circuit component.

FIG. 2 shows a flowchart regarding the method for manufacturing a cubic circuit substrate according to the first embodiment of the present invention, while FIGS. 3(a) to (d) show the substrate of the cubic circuit in the main step of the method for manufacturing the same in the order of procedure. The manufacture method of the present invention is a method for manufacturing a cubic circuit substrate comprising a circuit on the surface of a molded product, which comprises, as shown in FIG. 2, a molded product formation step (S1) in which a molded product having a desired cubic shape and trenches which are to be a wiring are formed, a base film formation step (S2) in which a nickel phosphorus film which is to be a first metal film is formed, a plating film formation step (S3) (also referred to as a wiring formation step.) in which trenches are filled by subjecting the surface of the first metal film to electroplating to form a circuit, and an unnecessary metal portion removal process (S4) in which unnecessary portions of the first metal film are removed, performed in the order stated.

For example, after the copper circuit component of the present invention is produced, via holes and outer layer circuits can be formed and further multilayering can be achieved by a conventionally known insulation layer forming process and a circuit formation step by heating and laminating prepregs and the like, if necessary. That is, it is also possible to produce a multilayered circuit.

The stability of the surface of the wiring can be improved by applying a solder resist and the like onto the surface of the above copper circuit component, and reliability can be also improved.

The present invention will be described below with reference to Examples, but the present invention is not limited to these descriptions.

### Example 1

FIG. 3 shows a manufacture process of the copper circuit component in Example of the present invention in FIG. 1. An insulating circuit component is formed by using PPS resin as an insulating base material, and formed into the shape of the cuboid-shaped component shown in FIG. 1 by injection molding. The outer dimension of the cuboid formed was 6 mm in width, 3 mm in height, and 3 mm in depth. As shown in FIG. 3(a), concave-shaped trenches were formed in the form of the wiring pattern on the surface of the insulating base material on one of the upper surface, lower surface and side surfaces of the component. The depth of the trenches in the form of the wiring was 10 μm; the width was 7 to 100 μm; and the intervals were 10 μm.

Next, as shown in FIG. 3(b), a first metal layer 3 was formed by electroless nickel plating. Top Chemialloy 66 manufactured by Okuno Chemical Industries Co., Ltd. was used for the electroless nickel plating. The nickel thickness was 200 nm. Vacuum evaporation, sputtering method, chemical vapor deposition (CVD) method, among others, can be used as the formation method of the base film. In addition, nickel, cobalt, chromium, tungsten, palladium, titanium and alloys of these elements can be used as the first metal layer. As shown in FIG. 3(c), a copper plating film 4 was then formed by the electrolytic copper plating. In the electroplating, 2-[(1,3-Dihydro-1,3,-trimethyl-2F-indol-2-ylidene)-methyl]-1,3,3-trimethyl-3H-indolium perchlorate was added to the plating solution shown in Table 1 as an additive.

TABLE 1
Composition and conditions of copper sulfate plating solution

| | |
|---|---|
| Copper sulfate pentahydrate | 150 g · dm⁻³ |
| Sulfuric acid | 180 g · dm⁻³ |
| Chloride ions | 50 mg · dm⁻³ |

As the plating conditions, the plating time was 10 minutes; the current density was 1.0 A/dm²; and the temperature of the plating solution was 25° C.

Cross sections of the wiring were observed after the electrolytic copper plating.

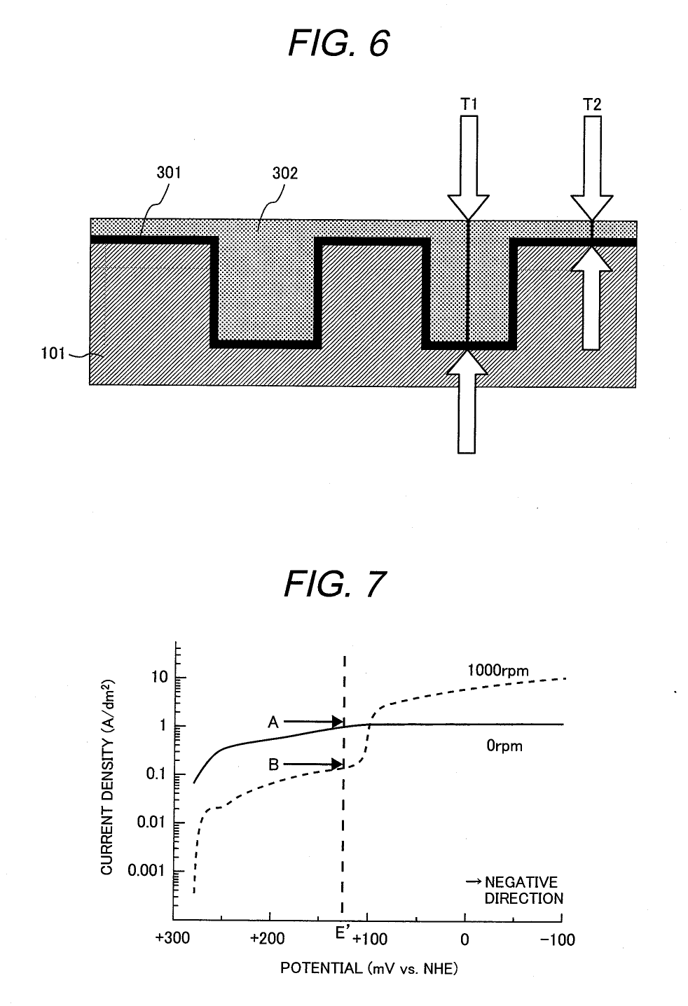

FIG. 6 is a partial cross-sectional view showing the state of wiring of a copper circuit component of an Example according to the present invention after plating.

The thickness T1 of the copper plating in the trenches for wiring shown in this Fig. and the thickness T2 of the copper plating on the surface other than on the wiring were determined.

As a result, the thickness T1 of the copper plating within the trenches for wiring was 10 μm, and the thickness T2 of the copper plating on the surface thereof was 0.001 μm or less.

This revealed that the second metal film 302 (copper plating film) was grown selectively within the trenches and were hardly deposited on the surface other than in the trenches.

Next, as shown in FIG. 3(d), the second metal film 302 (copper plating film) and the first metal film 301 (nickel layer) existing on the surface other than in the trenches were removed. CH-1935 manufactured by MEC Company Co., Ltd. was used for the removal of the nickel layer. Melstrip made by Meltex, Inc., or SEEDLON process made by Ebara-Udylite may be used for removing the nickel film. The copper plating film formed on the surface could be removed simultaneously with the nickel film. Accordingly, the removal process of the copper plating film on the surface is unnecessitated, and the manufacture of a minute copper circuit component in which minute copper wirings with a wiring width of 7 to 100 μm are embedded in the insulating base material was facilitated. When handling of the obtained component was conducted with a pincette, it could be handled with no peeling of copper wirings since the wirings were embedded in the insulating base material.

Furthermore, a component in which electrical contacts were made alternately in the wiring sections on the upper surface and lower surface of the component, and then the portions other than the contacts were covered with a solder resist was also formed. The voltage of 60 V was applied, and an insulation reliability test was carried out in an environment at 85° C. and 85%. As a result, in the component which is not covered with the solder resist, oxidation of the surface of the wirings has proceeded, but, in the component which is covered with the solder resist, no migration or other problems was observed even after 1000 hours and even in the wiring section with the minimum wire width of 7 μm, and the insulation resistance decreased only by 3%. The above results show that highly reliable micro-wiring could be formed on a component having a three-dimensional structure.

### Example 2

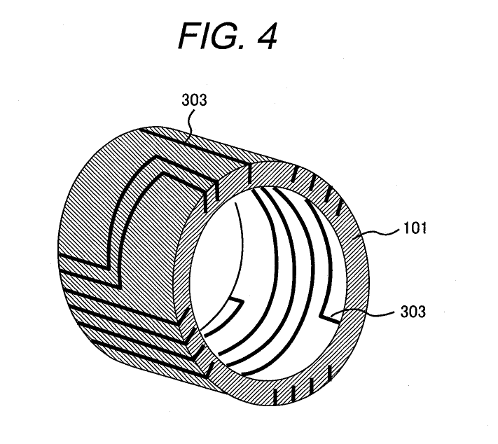

FIG. 4 shows another example according to the present invention.

FIG. 4 is also a schematic diagram showing another electronic circuit component (copper circuit component) of another example according to the present invention. In this figure, a cylindrical insulating material 101 is used as a substrate. Trenches (recessed portions) are provided on the outside and inside of the cylinder, and wirings 303 are embedded within the trenches.

A cylindrical minute component was formed by injection molding in a manner similar to that in Example 1. The outer dimension of the cylindrical component formed was 6 mm in diameter and 6 mm in height, and the thickness of the insulating base material was 1 mm. Concave-shaped trenches were formed in the form of the wiring pattern on the outer surface and inner surface of the component. The depth of the trenches in the form of the wiring was 10 μm, and the width was 7 to 100 μm. A seed layer was formed and the electrolytic copper plating and the seed layer were removed in a manner similar to that of Example 1. As a result, the manufacture of a minute copper circuit component in which the minute copper wiring is embedded within the insulating base material was facilitated. When handling of the obtained component was conducted with a pincette, the component could be handled with no peeling of the copper wirings since the wirings were embedded in the insulating base material.

Furthermore, a component in which electrical contacts were made alternately in the wiring sections on the upper surface and lower surface of the component, and then the portions other than the contacts which were covered with a solder resist was also formed. An insulation reliability test was carried out with a voltage of 60 V applied in an environment at 85° C. and 85%. As a result, the component which is not covered with the solder resist, oxidation of the surface of the wirings has proceeded, while in the component which is covered with the solder resist, no migration or other problems was observed even after 1000 hours and even in the wiring section with the minimum wire width of 7 μm, and the insulation resistance decreased only by 3%.

The above results show that highly reliable micro-wiring could be formed on a component having a three-dimensional structure. The manufacture of a minute copper circuit component having a minute copper wiring with a wiring width of 7 to 100 μm was facilitated. In addition, micro-wiring could be also formed on the inner surface readily. Electrical contacts were made alternately in the wiring sections of the upper surface and lower surface of the obtained component, and the portions other than the contacts were covered with a solder resist. An insulation reliability test was carried out with a voltage of 60 V applied and in an environment at 85° C. and 85%. As a result, no migration or other problems was observed even after 1000 hours and even in the wiring section with minimum wire width of 7 μm, and the insulation resistance decreased only by 4%.

The above results show that highly reliable micro-wiring could be formed on a component having a three-dimensional structure.

### Example 3

In this example, a cuboidal component similar to that in Example 1 was formed by injection molding. PTFE, polycarbonate, PEEK and PPS were used in the injection molding as insulating materials. Trenches for the wiring patterns were formed on the outer surface of each insulating material component in a manner similar to that in Example 1 except that the depth of the trenches was 15 μm; the width was 7, 10, 20, 50 and 100 μm; and the height-to-width ratio of the wirings was 2 or higher at the maximum. Even in this case, the manufacture of a minute copper circuit component in which the minute copper wiring is embedded within the insulating base material was facilitated as in Example 1. When handling of the obtained component was conducted with a pincette, all the insulating base materials of PTFE, polycarbonate, PEEK and PPS could be handled with no peeling of wiring since the wirings were embedded within the insulating base material.

Furthermore, a component in which electrical contacts were made alternately in the wiring sections on the upper surface and lower surface of the component, and then the portions other than the contacts were covered with a solder resist was also formed. An insulation reliability test was carried out with a voltage of 60 V applied and in an environment at 85° C. and 85%. As a result, in the component which is not covered with the solder resist, oxidation of the surface of the wirings has proceeded, while in the component which is covered with the solder resist, no migration or other problems was observed even after 1000 hours and even in the wiring section with the minimum wire width of 7 μm, and the insulation resistance decreased only by 3%. The above results show that highly reliable micro-wiring could be formed on a component having a three-dimensional structure.

### Example 4

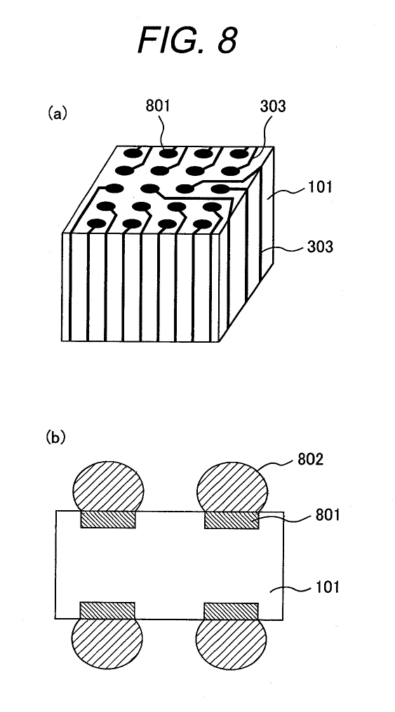

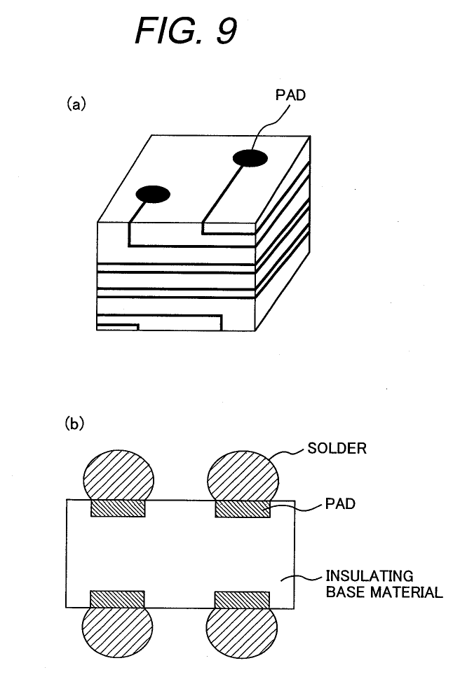

FIG. 8 shows an electronic circuit component of another example according to the present invention; FIG. 8(a) is a perspective view of the same; and FIG. 8(b) is a partial cross-sectional view of the same. FIG. 9 shows a variant of FIG. 8; FIG. 9(a) is a perspective view of the same; and FIG. 9(b) is a partial cross-sectional view of the same.

In FIGS. 8(a) and (b), pads 801 for connecting with external electrical components are formed on the upper surface and lower surface of the insulating base material 101, and the pads 801 on those upper surface and lower surface are connected via wirings 303. A cuboidal minute component was formed in a manner similar to that in Example 1. The outer dimension of the cuboid formed was 1 mm in width, 0.5 mm in height, and 0.5 mm in depth. As shown in FIG. 8(a), the wirings 303 are provided in such a manner that the upper surface and lower surface of the insulating base material 101 are connected by the shortest distance around the insulating base material 101.

After the electronic circuit component is formed, solders 802 are provided on the pads 801 as shown in FIG. 8(b).

Likewise, as shown in FIGS. 9(a) and (b), an electronic circuit component in which the wirings 303 are formed on the side surfaces of the insulating base material 101 in the form of a coil could be readily formed.

The above results show that the manufacture of a minute copper circuit component in which the minute copper wiring is embedded within the insulating base material was facilitated. When handling of the obtained component was conducted with a pincette, the copper wirings could be handled with no peeling of the copper wirings since the wirings were embedded in the insulating base material.

Furthermore, the portions other than the connecting pads on the upper surface and lower surface of the component were covered with a solder resist, and then solder balls were mounted to make electrical contacts. An insulation reliability test was carried out with a voltage of 60 V applied and in an environment at 85° C. and 85%. As a result, no migration or other problems was observed even after 1000 hours and even in the wiring section with the minimum wire width of 7 μm, and the insulation resistance decreased only by 3%. The above results show that highly reliable micro-wiring could be formed on a component having a three-dimensional structure.

It is possible to produce a multilayered circuit by stacking (laminating) a plurality of electronic circuit components having the above-mentioned constitution.

### Example 5

In this example, a cuboidal component was formed by injection molding.

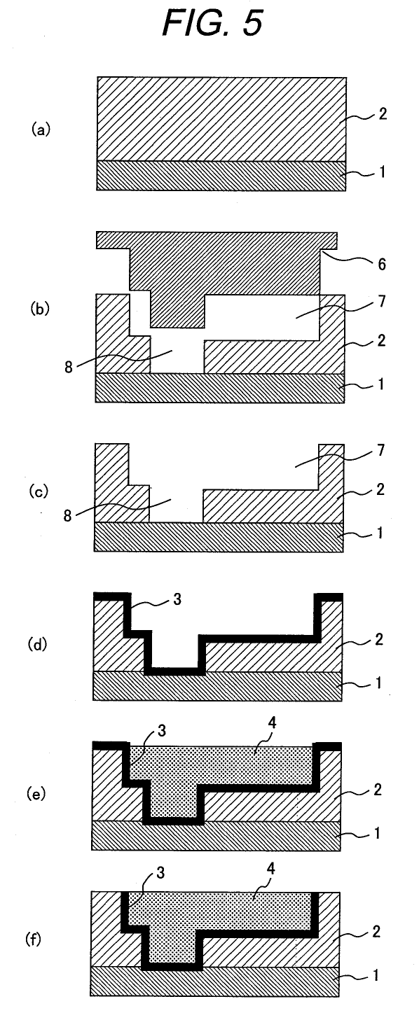

FIG. 5 is a partial cross-sectional view of a substrate showing a method for forming wirings according to the present invention.

FIG. 5(a) shows the state that a thermoplastic resin 2 (PEI in this example) is applied onto the surface of an insulating base material 1 formed by injection molding. FIG. 5(b) is a step for pressing a mold 6 against the thermoplastic resin 2 to process a wiring trench pattern with a depth of 7 μm and a width of 7 to 100 μm, and FIG. 5(c) shows a wiring trench 7 and a connection via 8 formed by the step. FIG. 5(d) shows the state that a first metal film 3 (first metal layer) is formed on the surfaces of the insulating base material 1 and the thermoplastic resin 2 by electroless nickel plating. FIG. 5(e) shows the state that a second metal film 4 (copper plating film) is formed on the surface of the first metal film 3 by the electrolytic copper plating. FIG. 5(f) shows the state that the metal film on the surface of the substrate other than the first metal film 3 and the second metal film 4 on the wiring trench 7 and the connection via 8 has been removed.

As a result, a minute copper circuit component in which minute copper wirings are embedded within the insulating base material could be also manufactured by this method. When handling of the obtained component was conducted with a pincette, the component could be handled with no peeling of copper wirings since the wirings were embedded in the insulating base material.

Furthermore, a component in which electrical contacts were made alternately in the wiring sections on the upper surface and lower surface of the component, and then the portions other than the contacts were covered with a solder resist was also formed. An insulation reliability test was carried out with a voltage of 60 V applied and in an environment at 85° C. and 85%. As a result, in the component which is not covered with the solder resist, oxidation of the surface of the wirings has proceeded, while in the component which is covered with the solder resist, no migration or other problems was observed even after 1000 hours and even in the wiring section with the minimum wire width of 7 μm, and the insulation resistance decreased only by 3%.

The above results show that highly reliable micro-wiring could be formed on a component having a three-dimensional structure.

### Example 6

In this example, a cuboidal component having a shape similar to that in Example 1 was formed by injection molding, and a copper circuit component in which wirings are embedded was produced. A resin was applied thereon in a manner similar to that in Example 5, and wiring trenches including connection vias 8 on the upper and lower wiring layers were formed. Plating was then conducted in a manner similar to that of Example 1.

As a result, two layers of minute copper wiring were also laminated by this method, and a minute copper circuit component embedded within the insulating base material could be produced. When handling of the obtained component was conducted with a pincette, the component could be handled with no peeling of copper wirings since the wirings were embedded in the insulating base material.

### Example 7

In this example, a cuboidal component having a shape similar to that in Example 1 was formed by injection molding, and a nickel seed was also formed in a similar manner. A commercially available copper sulfate plating solution for filling vias (in this example, CU-BRITE-VF4 manufactured by Ebara-Udylite Co., Ltd.) was used as an electrolytic copper plating solution after seed formation. As the plating conditions, the current density was 1.5 A/dm², and the temperature of the plating solution was 25° C.

Cross sections of the wiring were observed after the electrolytic copper plating.

As shown in FIG. 6, the thickness T1 of the copper plating in the trenches for wiring and the thickness T2 of the copper plating on the surface other than in the wiring portions were determined. As a result, the thickness T1 of the copper plating within the trenches for wiring was 10 μm, while the thickness T2 of the copper plating on the surface thereof was 4 μm.

These results show that the second metal film 302 (copper plating film) was grown preferentially within the trenches, but was also deposited and formed on the surface other than in the trenches.

Next, the second metal film 302 (copper plating film) and the first metal film 301 (nickel layer) existing on the surface other than in the trenches were removed. The unwanted copper plating film was etched with an aqueous solution of ferric chloride, and CH-1935 manufactured by MEC Company Co., Ltd. was used for the removal of the nickel layer.

As a result, a minute copper circuit component in which a minute copper wiring having a wiring width of 7 to 100 μm is embedded within the insulating base material could be produced, although the removal process of the copper plating film on the surface other than in the trenches was necessary. When handling of the obtained component was conducted with a pincette, the component could be handled with no peeling of copper wirings since the wirings were embedded in the insulating base material.

Furthermore, electrical contacts were made alternately in the wiring sections on the upper surface and lower surface of the component, a component in which the portions other than the contacts were covered with a solder resist was also formed. An insulation reliability test was carried out with a voltage of 60 V applied and in an environment at 85° C. and 85%. As a result, in the component which is not covered with the solder resist, oxidation of the surface of the wirings has proceeded, while in the component which is covered with the solder resist, no migration or other problems was observed even after 1000 hours and even in the wiring section having a minimum wire width of 7 μm, and the insulation resistance decreased only by 6%.

The above results show that highly reliable micro-wiring could be formed on a component having a three-dimensional structure.

### INDUSTRIAL APPLICABILITY

The electronic circuit component of the present invention can be applied to small-sized electronic devices and the like.

### EXPLANATION OF REFERENCES

1 Insulating base material
2 Thermoplastic resin
3 First metal film
4 Second metal film
7 Wiring trench
8 Connection via
101 Insulating base material
102 Recessed portion

1. An electronic circuit component having a pattern of a three-dimensional wiring on an insulating base material which serves as a foundation of an electronic circuit, wherein the wiring is embedded within the insulating base material.

2. The electronic circuit component according to claim 1, wherein the insulating base material has a recessed portion which is to be a wiring on the surface thereof in the form of a three-dimensional pattern, and the recessed portion has a first metal layer and a second metal layer which are to be the wirings therein.

3. The electronic circuit component according to claim 1, wherein a minimum width of the wiring is 20 μm or less.

4. The electronic circuit component according to claim 1, wherein a height-to-width ratio of the wiring is 1.5 or higher at the maximum.

5. The electronic circuit component according to claim 1, wherein a barrier film is formed on a bottom surface and a side surface of the wiring.

6. The electronic circuit component according to claim 5, wherein the barrier film comprises nickel or cobalt as a main component.

7. The electronic circuit component according to claim 1, wherein the wiring is provided on at least one of an outer surface and an inner surface of the insulating base material.

8. The electronic circuit component according to claim 1, comprising a multilayered circuit portion laminating a plurality of layers of circuit patterns by interposing an insulating layer on at least one surface of the insulating base material.

9. The electronic circuit component according to claim 1, wherein at least one portion of a shape of the insulating base material is a curved surface.

10. The electronic circuit component according to claim 1, wherein the shape of the insulating base material is spherical.

11. A method for manufacturing an electronic circuit component comprising the steps of forming a recessed portion which is to be a wiring on a surface of an insulating base material of the electronic circuit component having three-dimensional wiring, forming a first metal layer which is to be an electric conductive layer for electrolysis plating on the surface of the insulating base material including the recessed portion, forming a second metal wiring layer which is to be the wiring only within the recessed portion which is to be the wiring selectively, and removing the first metal layer formed on the surface other than in the recessed portion which are to be the wiring.

12. The method for manufacturing the electronic circuit component according to claim 11, wherein the second metal layer is copper.

13. The method for manufacturing the electronic circuit component according to claim 11, wherein the step of forming the second metal layer is conducted by electroplating using a plating solution containing a substance which increases deposition overvoltage for a metal which is to be the wiring on the surface of the first metal layer.

14. The method for manufacturing the electronic circuit component according to claim 11, wherein the plating solution used in the formation of the second metal layer is a copper sulfate electroplating solution, and has a property of having a potential region in which the current value when the electrode rotates at 1000 rpm is 1/100 or less of that when the electrode is stationary in a polarization curve obtained by measurement with a rotating disk electrode.

15. The method for manufacturing the electronic circuit component according to claim 11, wherein the plating solution used in the formation of the second metal layer is a copper sulfate electroplating solution, and is such that a current value when the electrode rotates at 1000 rpm to a current value when the electrode is stationary is 1/100 or less in the range of 100 to 200 mV, and a current value when the electrode rotates is larger than a current value when the electrode is stationary in the range of −100 mV or less with respect to standard hydrogen electrode potential in a polarization curve obtained by measurement with a rotating disk electrode.

16. The method for manufacturing the electronic circuit component according to claim 11, wherein the copper plating solution comprises at least one of cyanine dye and derivatives thereof.

17. The method for manufacturing the electronic circuit component according to claim 11, wherein the cyanine dye is represented by the following Chemical Formula (1) (n is any one of 0, 1, 2 and 3).

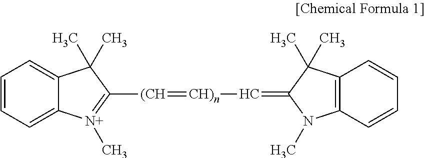

18. The method for manufacturing the electronic circuit component according to claim 11, wherein the first metal layer and the second metal layer are both copper.

19. The method for manufacturing the electronic circuit component according to claim 11, wherein the first metal layer is nickel, cobalt, chromium, tungsten, palladium or titanium, or an alloy comprising at least any one of nickel, cobalt, chromium, tungsten, palladium and titanium, and the second metal layer is copper.

20. An electronic circuit component comprising an insulating base material having a recessed portion, and a wiring embedded within the recessed portion, wherein the wiring comprises a first metal member closely fitted onto the internal surface of the recessed portion, and a second metal member closely fitted onto the first metal member.

21. The electronic circuit component according to claim 20, wherein the second metal member fills the recessed portion.

22. The electronic circuit component according to claim 20, wherein the wiring has a three-dimensional circuit pattern.
